(19) United States
(12) Patent Application Publication
(10) Pub. No.: US 2026/0190378 A1
(43) Pub. Date: Jul. 2, 2026

(54) SEMICONDUCTOR STRUCTURE AND FABRICATION METHOD THEREOF

(71) Applicant: Semiconductor Manufacturing International (Shanghai) Corporation, Shanghai (CN)

(72) Inventor: Jisong JIN, Shanghai (CN)

(21) Appl. No.: 19/437,942

(22) Filed: Dec. 31, 2025

(30) Foreign Application Priority Data
Jan. 2, 2025 (CN) 202510009395.X

(51) Int. Cl. H10D 30/00; H10D 30/01; H10D 62/10; H10D 62/832; H10D 64/01; H10D 64/66

(52) U.S. Cl. CPC H10D 30/502; H10D 30/019; H10D 62/102; H10D 62/832; H10D 64/017; H10D 64/675

(57) ABSTRACT

A semiconductor structure and a fabrication method of the semiconductor structure are provided in the present disclosure. The semiconductor structure includes a base substrate; a channel-layer structure suspended above the base substrate; a gate structure over the substrate and crossing the channel-layer structure; a gate spacer crossing the channel-layer structure and covering a sidewall of the gate structure; a dummy gate dielectric layer, covering a portion of a sidewall and a portion of a top of the channel-layer structure at a position that the gate spacer crosses the channel-layer structure; and an inner spacer, on a sidewall of the gate structure between adjacent channel layers. Along the extension direction of the channel layer, an end of the dummy gate dielectric layer is in a contact with the gate structure, and another end of the dummy gate dielectric layer is recessed relative to an outer sidewall of the gate spacer.

### CROSS-REFERENCE TO RELATED APPLICATION

This application claims the priority of Chinese Patent Application No. 202510009395.X, filed on Jan. 2, 2025, the content of which is incorporated herein by reference in its entirety.

### TECHNICAL FIELD

The present disclosure generally relates to the field of semiconductor manufacturing and, more particularly, relates to a semiconductor structure and a fabrication method thereof.

### BACKGROUND

In semiconductor manufacturing, with the development of super large-scale integrated circuits, the feature sizes of integrated circuits continue to decrease. To adapt to smaller feature sizes, the channel lengths of metal-oxide-semiconductor field-effect transistors (MOSFET) have also been reduced accordingly. However, as the device channel length is reduced, the distance between a source electrode and a drain electrode of the device may also be reduced. Therefore, the gate structure's ability to control the channel may become worse, and it may be increasingly difficult for the gate voltage to pinch off the channel, which may result in subthreshold leakage phenomenon. That is, so-called short-channel effects (SCE) may be more likely to occur.

Therefore, to better adapt to the requirements of scaling down device sizes, semiconductor processes have gradually begun to transition from planar transistors to three-dimensional transistors with higher efficiency, such as gate-all-around (GAA) transistors. In the gate-all-around metal gate transistor, the gate structure may surround the region where the channel is located from all sides. Compared with the planar transistor, the gate structure of the gate-all-around metal-gate transistor may have stronger control over the channel and better suppress the short channel effect.

### SUMMARY

One aspect of the present disclosure provides a semiconductor structure. The semiconductor structure includes a base substrate; a channel-layer structure, suspended above the base substrate, where the channel-layer structure includes one or more channel layers spaced apart from each other along a vertical direction; a gate structure, over the substrate and crossing the channel-layer structure, where the gate structure is around the one or more channel layers along a direction perpendicular to an extension direction of a channel layer of the one or more channel layers; a gate spacer, crossing the channel-layer structure and covering a sidewall of the gate structure; a dummy gate dielectric layer, between the gate spacer and the channel-layer structure and covering a portion of a sidewall and a portion of a top of the channel-layer structure at a position that the gate spacer crosses the channel-layer structure, where along the extension direction of the channel layer, an end of the dummy gate dielectric layer is in a contact with the gate structure, and another end of the dummy gate dielectric layer is recessed relative to an outer sidewall of the gate spacer; and an inner spacer, on a sidewall of the gate structure between adjacent channel layers.

Optionally, between the gate spacer and the channel-layer structure, the another end of the dummy gate dielectric layer, which is recessed relative to the outer sidewall of the gate spacer, and a bottom of the gate spacer form a recess, the recess surrounding the top and the sidewall of the channel-layer structure; and the inner spacer is further filled in the recess.

Optionally, a distance between the outer sidewall of the gate spacer and the another end of the dummy gate dielectric layer recessed relative to the outer sidewall of the gate spacer is about 3 Å to 20 Å.

Optionally, the semiconductor structure further includes a source-drain doped layer, on the base substrate at two sides of the gate structure, where the source-drain doped layer is in a contact with an end of the channel-layer structure.

Optionally, the channel layer is made of a material including silicon, germanium, silicon germanium, a Group III-V semiconductor material, or a combination thereof.

Optionally, the gate spacer is made of a material including silicon oxide, silicon nitride, silicon carbide, silicon carbonitride, silicon oxycarbonitride, silicon oxynitride, boron nitride, boron carbonitride, or a combination thereof.

Optionally, the inner spacer is made of a material including silicon nitride, silicon oxynitride, silicon oxycarbonitride, silicon oxycarbide, hydrogenated silicon oxycarbide, or a combination thereof.

Another aspect of the present disclosure provides a fabrication method of a semiconductor structure. The method includes providing a stacked-layer structure on a base substrate, where the stacked-layer structure includes sacrificial layers and channel layers alternately stacked along a vertical direction; along a direction perpendicular to an extension direction of a channel layer, forming a dummy gate dielectric layer, crossing the stacked-layer structure and covering a top and a sidewall of the stacked-layer structure, on the base substrate; forming a dummy gate layer, crossing the stacked-layer structure and covering the dummy gate dielectric layer, on the dummy gate dielectric layer; forming a gate spacer on a sidewall of the dummy gate layer; removing a portion of the dummy gate dielectric layer from the sidewall of the stacked-layer structure along the extension direction of the channel layer to expose a portion of each sacrificial layer; removing a portion of each sacrificial layer along the extension direction of the channel layer through the exposed portion of each sacrificial layer to form a groove on each side of the sacrificial layer; forming an inner spacer in the groove; removing the dummy gate layer, a portion of the dummy gate dielectric layer covered by the dummy gate layer, and the sacrificial layers, thereby retaining the channel layers, spaced apart from each other and suspended above the base substrate, as a channel-layer structure; and forming a gate structure crossing the channel-layer structure, where the gate structure is around each channel layer along the direction perpendicular to the extension direction of the channel layer.

Optionally, for removing the portion of the dummy gate dielectric layer from the sidewall of the stacked-layer structure along the extension direction of the channel layer to expose the portion of each sacrificial layer, the portion of the dummy gate dielectric layer is removed from the sidewall of the stacked-layer structure along the extension direction of the channel layer to form a recess, where the recess surrounds a top and a sidewall of the stacked-layer structure between the gate spacer and the stacked-layer structure; and for forming the inner spacer in the groove, the inner spacer is further filled in the recess.

Optionally, for removing the portion of the dummy gate dielectric layer from the sidewall of the stacked-layer structure along the extension direction of the channel layer to expose the portion of each sacrificial layer, a width of removed dummy gate dielectric layer is about 3 Å to 20 Å.

Optionally, an isotropic etching process is configured to remove the portion of the dummy gate dielectric layer from the sidewall of the stacked-layer structure along the extension direction of the channel layer to expose the portion of each sacrificial layer.

Optionally, for removing the portion of the dummy gate dielectric layer from the sidewall of the stacked-layer structure along the extension direction of the channel layer by the isotropic etching process, an etching selectivity ratio between the dummy gate dielectric layer and the channel layer is greater than or equal to 5.

Optionally, an isotropic etching process is configured to remove the portion of each sacrificial layer along the extension direction of the channel layer through the exposed portion of each sacrificial layer to form the groove.

Optionally, before removing the portion of the dummy gate dielectric layer from the sidewall of the stacked-layer structure along the extension direction of the channel layer to expose the portion of each sacrificial layer, the method further includes removing a portion of each sacrificial layer from the sidewall of the stacked-layer structure along the extension direction of the channel layer, and forming an initial groove surrounded by adjacent channel layers along a vertical direction; removing the portion of the dummy gate dielectric layer from the sidewall of the stacked-layer structure along the extension direction of the channel layer to expose the portion of each sacrificial layer includes exposing sidewalls of each sacrificial layer on two sides of the initial groove along a direction perpendicular to the extension direction of the channel layer; and for removing the portion of each sacrificial layer along the extension direction of the channel layer through the exposed portion of each sacrificial layer to form the groove includes removing the portion of each sacrificial layer through the initial groove and the exposed portion of each sacrificial layer to form the groove.

Optionally, an isotropic etching process is configured to remove the portion of each sacrificial layer from the sidewall of the stacked-layer structure along the extension direction of the channel layer, and form the initial groove surrounded by adjacent channel layers along the vertical direction.

Optionally, forming the inner spacer in the groove and before removing the dummy gate layer, the portion of the dummy gate dielectric layer covered by the dummy gate layer and the sacrificial layers, the method further includes forming a source-drain doped layer, on the base substrate at two sides of the gate structure, where the source-drain doped layer is in a contact with an end of the channel-layer structure.

Optionally, removing the dummy gate layer, the portion of the dummy gate dielectric layer covered by the dummy gate layer, and the sacrificial layers includes: removing the dummy gate layer to expose the dummy gate dielectric layer between adjacent gate spacers; removing the dummy gate dielectric layer between adjacent gate spacers to expose the stacked-layer structure; and removing the sacrificial layers in the stacked-layer structure, thereby retaining the channel layers, spaced apart from each other and suspended above the base substrate, as the channel-layer structure.

Optionally, for providing the base substrate, the channel layer is made of a material including silicon, germanium, silicon germanium, a Group III-V semiconductor material, or a combination thereof.

Optionally, the gate spacer is made of a material including silicon oxide, silicon nitride, silicon carbide, silicon carbonitride, silicon oxycarbonitride, silicon oxynitride, boron nitride, boron carbonitride, or a combination thereof.

Optionally, the inner spacer is made of a material including silicon nitride, silicon oxynitride, silicon oxycarbonitride, silicon oxycarbide, hydrogenated silicon oxycarbide, or a combination thereof.

Compared with the existing technology, the technical solutions provided by the present disclosure may achieve at least the following beneficial effects.

In the semiconductor structure provided by embodiments of the present disclosure, the dummy gate dielectric layer may be between the gate spacer and the channel-layer structure and cover a portion of the sidewall and a portion of the top of the channel-layer structure where the gate spacer crosses the channel-layer structure; along the extension direction of the channel layer, one end of the dummy gate dielectric layer may be in contact with the gate structure, and the other end of the dummy gate dielectric layer may be recessed relative to the outer sidewall of the gate spacer; and the inner spacer may be on the sidewall of the gate structure between adjacent channel layers. In embodiments of the present disclosure, during the semiconductor manufacturing process, the stacked-layer structure including sacrificial layers and channel layers alternately stacked from bottom to top along the vertical direction, the dummy gate dielectric layer crossing the stacked-layer structure, the dummy gate layer covering the dummy gate dielectric layer, and the gate spacer on the sidewall of the dummy gate layer may be first formed; a portion of the dummy gate dielectric layer may be removed to expose a portion (sidewall) of the sacrificial layer; a portion of the sacrificial layer may be removed through exposed portion (sidewall) of the sacrificial layer to form the groove; after the inner spacer is formed in the groove, the dummy gate layer, the dummy gate dielectric layer covered by the dummy gate layer, and the sacrificial layer may be removed; and the gate structure crossing the channel-layer structure and surrounding the channel layer may be formed at corresponding position. Therefore, the dummy gate dielectric layer may be retained between the gate spacer and the channel-layer structure, and one end of the dummy gate dielectric layer may be in contact with the gate structure, and the other end of the dummy gate dielectric layer may be recessed relative to the outer sidewall of the gate spacer. During the semiconductor manufacturing process, when the portion of the sacrificial layer is subsequently removed to form the groove, the part which is closer to the edge of the sacrificial layer may be more difficult to be removed. Particularly at the contact position between the stacked-layer structure and the dummy gate dielectric layer, oxygen in the dummy gate dielectric layer may diffuse into the sacrificial layer, which may be more difficult to remove the material at the contact position between the sacrificial layer and the dummy gate dielectric layer. In embodiments of the present disclosure, a portion of the dummy gate dielectric layer may be removed from the sidewall of the stacked-layer structure along the extension direction of the channel layer, thereby exposing the sidewall of the sacrificial layer. That is, the portion of the sacrificial layer originally in contact with the dummy gate dielectric layer may be exposed, such that the part near the edge of the sacrificial layer along the direction perpendicular to the extension direction of the channel layer may be easily to be removed. In the operation of removing the portion of the sacrificial layer along the extension direction of the channel layer through the exposed portion (sidewall) of the sacrificial layer, the process window of removing the portion of the sacrificial layer may be increased, which may be beneficial for ensuring sufficient space at two sides of the groove along the direction perpendicular to the extension direction of the channel layer. In such way, the space for forming the inner spacer may be sufficient, which may be beneficial for ensuring that the inner spacer has sufficient thickness at two sides along the direction perpendicular to the extension direction of the channel layer, thereby being beneficial for ensuring the isolation effect of the inner spacer. During the operation of removing the sacrificial layer, it is beneficial for ensuring the protection of the inner spacer on the external structure and reducing the probability of damage to the external structure of the inner spacer due to excessive thinness of the inner spacer at two sides along the direction perpendicular to the extension direction of the channel layer during the removal of the sacrificial layer. Accordingly, during the process of forming the gate structure, the isolation effect between the gate structure and the external structure of the inner spacer may be ensured, thereby being beneficial for improving the operating performance of the semiconductor structure.

In the fabrication method provided by embodiments of the present disclosure, a portion of the dummy gate dielectric layer may be removed from the sidewall of the stacked-layer structure along the extension direction of the channel layer to expose a portion (sidewall) of the sacrificial layer; a portion of the sacrificial layer may be removed from exposed portion (sidewall) of the sacrificial layer along the extension direction of the channel layer to form the groove; and the inner spacer may be formed in the groove. During the semiconductor manufacturing process, when the portion of the sacrificial layer is subsequently removed to form the groove, the part which is closer to the edge of the sacrificial layer may be more difficult to be removed. Particularly at the contact position between the stacked-layer structure and the dummy gate dielectric layer, oxygen in the dummy gate dielectric layer may diffuse into the sacrificial layer, which may be more difficult to remove the material at the contact position between the sacrificial layer and the dummy gate dielectric layer. In embodiments of the present disclosure, a portion of the dummy gate dielectric layer may be removed from the sidewall of the stacked-layer structure along the extension direction of the channel layer, thereby exposing the sidewall of the sacrificial layer. That is, the portion of the sacrificial layer originally in contact with the dummy gate dielectric layer may be exposed, such that the part near the edge of the sacrificial layer along the direction perpendicular to the extension direction of the channel layer may be easily to be removed. In the operation of removing the portion of the sacrificial layer along the extension direction of the channel layer through the exposed portion (sidewall) of the sacrificial layer, the process window of removing the portion of the sacrificial layer may be increased, which may be beneficial for ensuring sufficient space at two sides of the groove along the direction perpendicular to the extension direction of the channel layer. In such way, the space for forming the inner spacer may be sufficient, which may be beneficial for ensuring that the inner spacer has sufficient thickness at two sides along the direction perpendicular to the extension direction of the channel layer, thereby being beneficial for ensuring the isolation effect of the inner spacer. During the operation of removing the sacrificial layer, it is beneficial for ensuring the protection of the inner spacer on the external structure and reducing the probability of damage to the external structure of the inner spacer due to excessive thinness of the inner spacer at two sides along the direction perpendicular to the extension direction of the channel layer during the removal of the sacrificial layer. Accordingly, during the process of forming the gate structure, the isolation effect between the gate structure and the external structure of the inner spacer may be ensured, thereby being beneficial for improving the operating performance of the semiconductor structure.

### BRIEF DESCRIPTION OF THE DRAWINGS

The following drawings are merely examples for illustrative purposes according to various disclosed embodiments and are not intended to limit the scope of the present disclosure.

FIGS. 1-6 illustrate structural schematics corresponding to certain stages of an exemplary fabrication method of a semiconductor structure.

FIG. 7-11 illustrate structural schematics of an exemplary semiconductor structure according to various disclosed embodiments of the present disclosure.

FIGS. 12-31 illustrate structural schematics corresponding to certain stages of an exemplary fabrication method of a semiconductor structure according to various disclosed embodiments of the present disclosure.

FIG. 32 illustrates a flowchart of an exemplary fabrication method of a semiconductor structure according to various disclosed embodiments of the present disclosure.

### DETAILED DESCRIPTION

References are made in detail to exemplary embodiments of the disclosure, which are illustrated in accompanying drawings. Wherever possible, same reference numbers are used throughout accompanying drawings to refer to same or like parts.

A semiconductor structure and a fabrication method of the semiconductor structure are provided in the present disclosure. The semiconductor structure includes a base substrate; a channel-layer structure, suspended above the base substrate, where the channel-layer structure includes one or more channel layers spaced apart from each other along a vertical direction; a gate structure, over the substrate and crossing the channel-layer structure, where the gate structure is around the one or more channel layers along a direction perpendicular to an extension direction of a channel layer of the one or more channel layers; a gate spacer, crossing the channel-layer structure and covering a sidewall of the gate structure; a dummy gate dielectric layer, between the gate spacer and the channel-layer structure and covering a portion of a sidewall and a portion of a top of the channel-layer structure at a position that the gate spacer crosses the channel-layer structure, where along the extension direction of the channel layer, an end of the dummy gate dielectric layer is in a contact with the gate structure, and another end of the dummy gate dielectric layer is recessed relative to an outer sidewall of the gate spacer; and an inner spacer, on a sidewall of the gate structure between adjacent channel layers.

Currently, the performance of current semiconductor structures needs to be improved. The present disclosure provides a semiconductor structure and a fabrication method of the semiconductor structure to overcome above-mentioned problems.

FIGS. 1-6 illustrate structural schematics corresponding to certain stages of an exemplary fabrication method of a semiconductor structure.

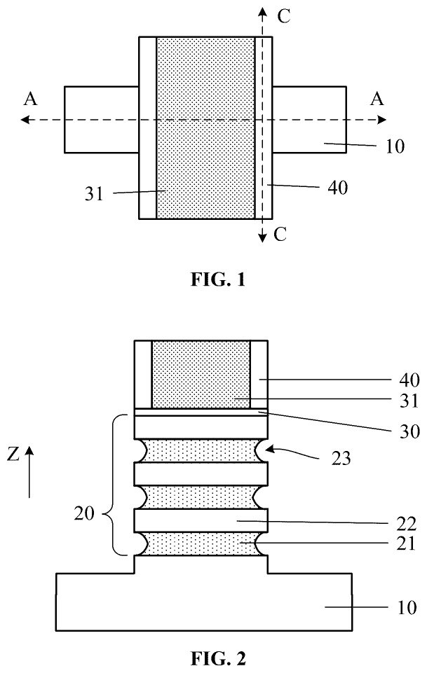

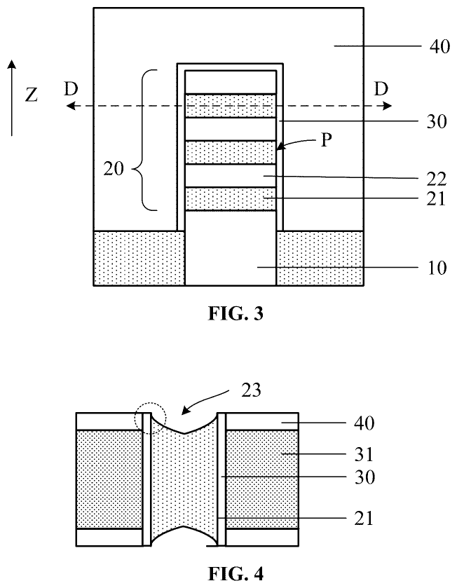

FIG. 1 illustrates a top view of a semiconductor structure, FIG. 2 illustrates a cross-sectional view along the AA direction in FIG. 1, FIG. 3 illustrates a cross-sectional view along the CC direction in FIG. 1, and FIG. 4 illustrates a cross-sectional view along the DD direction in FIG. 3. Referring to FIGS. 1-4, a base substrate 10 may be provided; a stacked-layer structure 20 may be suspended above the base substrate 10; the stacked-layer structure 20 may include sacrificial layers 21 and channel layers 22 alternately stacked along the vertical direction (the Z direction as shown in FIG. 2) from bottom to top; a dummy gate dielectric layer 30 covering the top and sidewalls of the stacked-layer structure 20, and a dummy gate layer 31 crossing the stacked-layer structure 24 and covering the dummy gate dielectric layer 30 may be also formed on the base substrate 10; a gate spacer 40 may be formed on the sidewall of the dummy gate layer 31; and a portion of the sacrificial layer 21 may be removed from the sidewall of the stacked-layer structure 20 along the extension direction of the channel layer 22 to form a groove 23 which may be surrounded by adjacent channel layers 22 along the vertical direction.

During the process of removing the portion of the sacrificial layer 21, the part which is closer to the edge of the sacrificial layer 21 may be more difficult to be removed. Particularly at the contact position between the stacked-layer structure 20 and the dummy gate dielectric layer 30, oxygen in the dummy gate dielectric layer 30 may diffuse into the sacrificial layer 21, which may be more difficult to remove the material at the contact position between the sacrificial layer 21 and the dummy gate dielectric layer 30. Therefore, during the operation of removing the portion of the sacrificial layer 21, the material at the contact position between the sacrificial layer 21 and the dummy gate dielectric layer 30 may be difficult to be removed (as indicated by the dotted circle in FIG. 4), which may result in insufficient space in the groove 23 for forming the inner spacer.

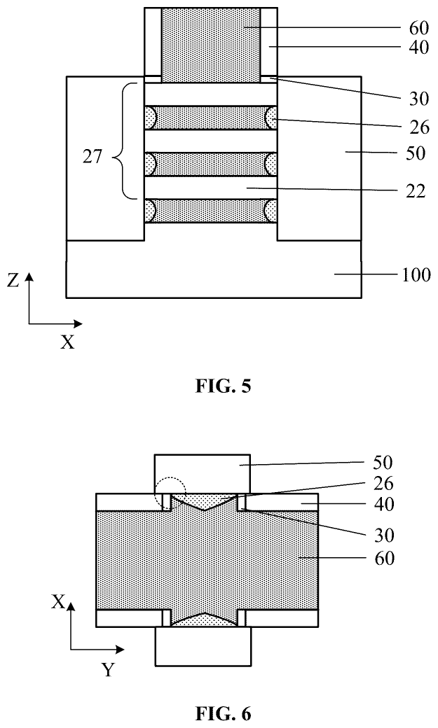

FIG. 5 illustrates a cross-sectional view corresponding to FIG. 2, and FIG. 6 illustrates a cross-sectional view corresponding to FIG. 4. Referring to FIGS. 5-6, the inner spacer 26 may be formed in the groove 23; a source-drain doped layer 50, which is in contact with the ends of the stacked-layer structure 20, may be formed on the base substrate 10 at two sides of the dummy gate layer 31; the dummy gate layer 31, the dummy gate dielectric layer 30 covered by the dummy gate layer 31, and the sacrificial layers 21 may be removed, thereby retaining a plurality of channel layers 22 as a channel-layer structure 27; and a gate structure 60, crossing the channel-layer structure 27 and surrounding and covering the channel layers 22, may be formed.

The space of the groove 23 for forming the inner spacer 26 may be not sufficient; and the inner spacer 26 may be too thin at two corresponding sides along the direction perpendicular to the extension direction of the channel layer 22. Therefore, during the operation of removing the sacrificial layer 21, the inner spacer 26 may be easily etched away, thereby damaging the source-drain doped layer 50. Consequently, during the formation of the gate structure 60, the isolation between the gate structure 60 and the source-drain doped layer 50 may be poor, which may affect the performance of the semiconductor structure.

To solve above-mentioned technical problems, embodiments of the present disclosure provide a fabrication method of a semiconductor structure. The fabrication method includes providing a stacked-layer structure on a base substrate, where the stacked-layer structure includes sacrificial layers and channel layers alternately stacked along a vertical direction; along a direction perpendicular to an extension direction of a channel layer, forming a dummy gate dielectric layer, crossing the stacked-layer structure and covering a top and a sidewall of the stacked-layer structure, on the base substrate; forming a dummy gate layer, crossing the stacked-layer structure and covering the dummy gate dielectric layer, on the dummy gate dielectric layer; forming a gate spacer on a sidewall of the dummy gate layer; removing a portion of the dummy gate dielectric layer from the sidewall of the stacked-layer structure along the extension direction of the channel layer to expose a portion of each sacrificial layer; removing a portion of each sacrificial layer along the extension direction of the channel layer through the exposed portion of each sacrificial layer to form a groove on each side of the sacrificial layer; forming an inner spacer in the groove; removing the dummy gate layer, a portion of the dummy gate dielectric layer covered by the dummy gate layer, and the sacrificial layers, thereby retaining the channel layers, spaced apart from each other and suspended above the base substrate, as a channel-layer structure; and forming a gate structure crossing the channel-layer structure, where the gate structure is around each channel layer along the direction perpendicular to the extension direction of the channel layer.

During the semiconductor manufacturing process, when the portion of the sacrificial layer is removed to form the groove, the part which is closer to the edge of the sacrificial layer may be more difficult to be removed. Particularly at the contact position between the stacked-layer structure and the dummy gate dielectric layer, oxygen in the dummy gate dielectric layer may diffuse into the sacrificial layer, which may be more difficult to remove the material at the contact position between the sacrificial layer and the dummy gate dielectric layer. In one embodiment, a portion of the dummy gate dielectric layer may be removed from the sidewall of the stacked-layer structure along the extension direction of the channel layer, thereby exposing the sidewall of the sacrificial layer. That is, the portion of the sacrificial layer originally in contact with the dummy gate dielectric layer may be exposed, such that the part near the edge of the sacrificial layer along the direction perpendicular to the extension direction of the channel layer may be easily to be removed. In the operation of removing the portion of the sacrificial layer along the extension direction of the channel layer through the exposed portion (sidewall) of the sacrificial layer, the process window of removing the portion of the sacrificial layer may be increased, which may be beneficial for ensuring sufficient space at two sides of the groove along the direction perpendicular to the extension direction of the channel layer. In such way, the space for forming the inner spacer may be sufficient, which may be beneficial for ensuring that the inner spacer has sufficient thickness at two sides along the direction perpendicular to the extension direction of the channel layer, thereby being beneficial for ensuring the isolation effect of the inner spacer. During the operation of removing the sacrificial layer, it is beneficial for ensuring the protection of the inner spacer on the external structure and reducing the probability of damage to the external structure of the inner spacer due to excessive thinness of the inner spacer at two sides along the direction perpendicular to the extension direction of the channel layer during the removal of the sacrificial layer. Accordingly, during the process of forming the gate structure, the isolation effect between the gate structure and the external structure of the inner spacer may be ensured, thereby being beneficial for improving the operating performance of the semiconductor structure.

In order to clearly illustrate above-mentioned described objectives, features, and advantages of the present disclosure, various embodiments of the present disclosure are described in detail with reference to accompanying drawings hereinafter.

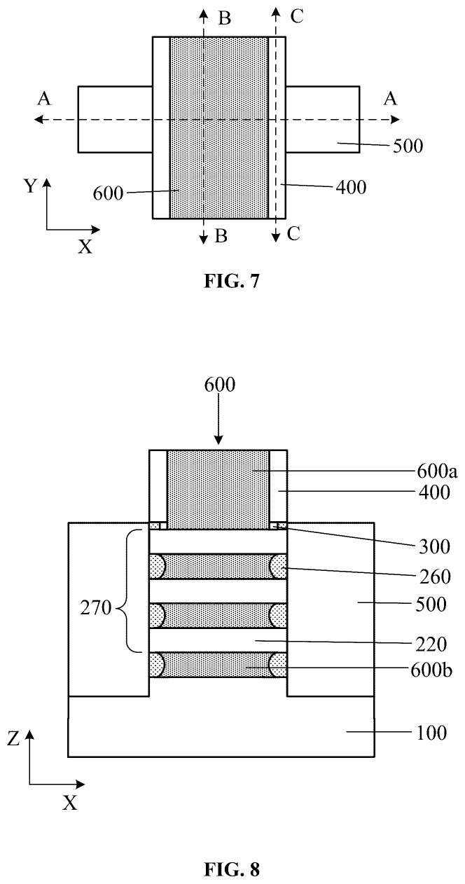

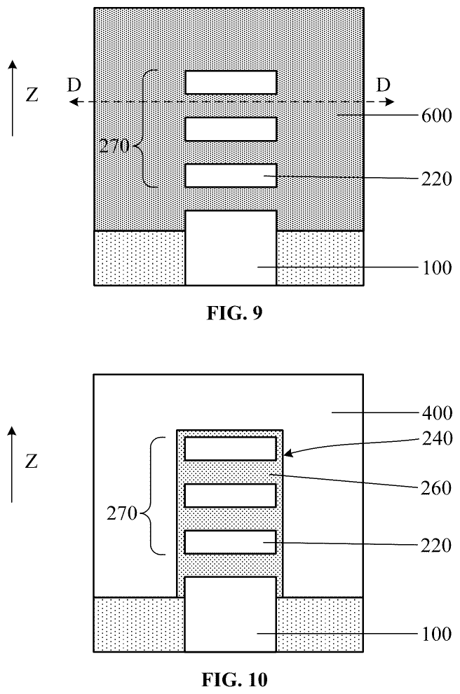

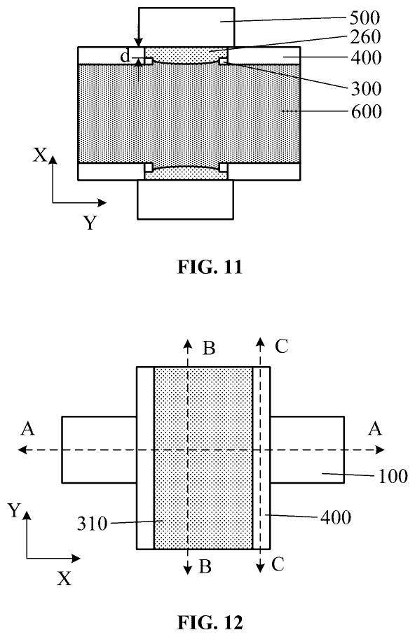

FIG. 7-11 illustrate structural schematics of an exemplary semiconductor structure according to various disclosed embodiments of the present disclosure. FIG. 7 illustrates a top view of a semiconductor structure, FIG. 8 illustrates a cross-sectional view along the AA direction in FIG. 7, FIG. 9 illustrates a cross-sectional view along the BB direction in FIG. 7, FIG. 10 illustrates a cross-sectional view along the CC direction in FIG. 7, and FIG. 11 illustrates a cross-sectional view along the DD direction in FIG. 9.

Referring to FIGS. 7-11, the semiconductor structure may include a base substrate 100; a channel-layer structure 270 suspended above the base substrate 100, where the channel-layer structure 270 may include one or more channel layers 220 spaced apart along the vertical direction (the Z direction as shown in FIG. 8); a gate structure 600 above the base substrate 100 and crossing the channel-layer structure 270, where the gate structure 600 may be around (surround) the channel layer 220 along the direction perpendicular to the extension direction of the channel layer 220 (the Y direction as shown in FIG. 7); a gate spacer 400 crossing the channel-layer structure 270 and covering the sidewall of the gate structure 600; a dummy gate dielectric layer 300 between the gate spacer 400 and the channel-layer structure 270 and covering a portion of the sidewall and a portion of the top of the channel-layer structure 270 at the position that the gate spacer 400 crosses the channel-layer structure 270, where along the extension direction of the channel layer 220 (the X direction as shown in FIG. 7), one end of the dummy gate dielectric layer 300 may be in contact with the gate structure 600, and another end of the dummy gate dielectric layer 300 may be recessed relative to the outer sidewall of the gate spacer 400; and an inner spacer 260 on the sidewall of the gate structure 600 between adjacent channel layers 220. In one embodiment, the gate structure 600 may include a first portion of the gate structure 600a, and one or more second portion of the gate structure 600b each around the channel layer 220. In another embodiment, the second portion of the gate structure 600b may be below the first portion of the gate structure 600a and between a source doped region and a drain doped region of a source-drain doped layer 500.

The base substrate 100 may provide the process operation basis (foundation) for the fabrication process of the semiconductor structure. The semiconductor structures may include gate-all-around (GAA) transistors and fork-sheet transistors.

In some embodiments, the base substrate 100 may be made of silicon. In other embodiments, the base substrate may also be made of other materials including germanium, silicon germanium, silicon carbide, gallium arsenide, indium gallium and/or the like. The base substrate may also be made of other types of substrates including a silicon-on-insulator substrate, a germanium-on-insulator substrate and/or the like. The material of the base substrate may be a material suitable for process needs or easy to integrate.

The channel-layer structure 270 may include one or more channel layers 220 spaced apart along the vertical direction; and the channel layer 220 may be configured as the channel of the transistor.

In one embodiment, the channel layer 220 may be made of a material including silicon, germanium, silicon germanium, a Group III-V semiconductor material, or a combination thereof. In one embodiment, the material of the channel layer 220 may be silicon. In other embodiments, the material of the channel layer may be determined by the type and performance of the transistor.

The gate structure 600 may be configured to control the turn-on and turn-off state of the transistor channel.

The gate structure 600 may be around and cover the channel layer 220. Therefore, the top, the bottom, and the sidewall of the channel layer 220 may all function as the channel, which may increase the area of the channel layer 220 available for the channel, thereby increasing the operating current of the semiconductor structure.

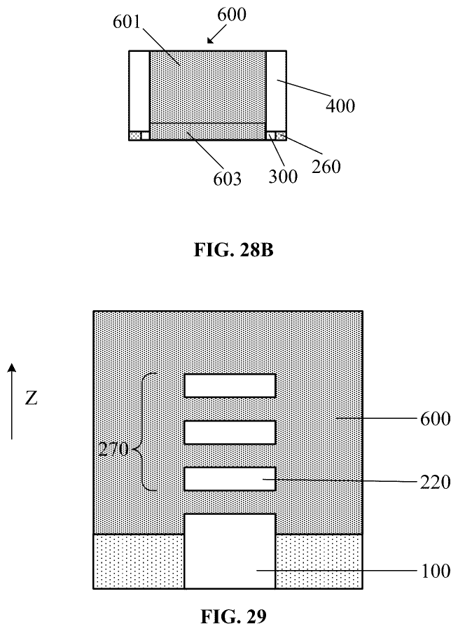

In one embodiment, the gate structure 600 may include a gate dielectric layer 603 (referring to FIG. 28B) surrounding the channel layer 220 along the extension direction of the gate structure 600, and a gate structure 603 (referring to FIG. 28B) on the gate dielectric layer.

The gate dielectric layer may be configured to isolate the gate structure from both the channel layer 220 and the base substrate 100.

The gate dielectric layer may be made of a material including HfO₂, ZrO₂, HfSiO, HfSiON, HfTaO, HfTiO, HfZrO, Al₂O₃, SiO₂, La₂O₃, and/or a combination thereof. In one embodiment, the gate dielectric layer may include a high-k gate dielectric layer; and the material of the high-k gate dielectric layer may include a high-k dielectric material. The high-k dielectric material refers to a dielectric material having a relative dielectric constant greater than the relative dielectric constant of silicon oxide. For example, the high-k gate dielectric layer may be made of a material including HfO₂, ZrO₂, HfSiO, HfSiON, HfTaO, HfTiO, HfZrO, Al₂O₃, and/or a combination thereof.

It should be noted that the gate dielectric layer may also include a gate oxide layer; and the gate oxide layer may be between the high-k gate dielectric layer and the channel layer 220. For example, the gate oxide layer may be made of silicon oxide.

In one embodiment, the gate structure 600 may be a metal gate structure. Therefore, the gate structure may be made of a material including TiN, TaN, Ta, Ti, TiAl, W, Al, TiSiN, TiAlC, and/or a combination thereof.

For example, the gate structure may include a work function layer (not shown), and an electrode layer (not shown) on the work function layer. The work function layer may be configured to adjust the threshold voltage of the transistor, and the electrode layer may be configured to lead out the electrical properties of the metal gate structure.

In other embodiments, the gate structure may include only the work function layer.

In other embodiments, according to process requirements, the gate structure may also be a polysilicon gate structure.

The gate spacer 400 may be configured to protect the sidewall of the gate structure 600.

In one embodiment, the gate spacer 400 may be a single-layer structure or a stacked-layer structure. The gate spacer 400 may be made of a material including silicon oxide, silicon nitride, silicon carbide, silicon carbonitride, silicon oxycarbonitride, silicon oxynitride, boron nitride, boron carbonitride, and/or a combination thereof. In one embodiment, the gate spacer 400 may be a single-layer structure and made of silicon nitride.

The dummy gate dielectric layer 300 may be configured to protect the channel layer 220 below the dummy gate dielectric layer 300 from damage during the semiconductor manufacturing process.

In one embodiment, in the semiconductor manufacturing process, the stacked-layer structure (including the sacrificial layers and the channel layers 220 alternately stacked vertically from bottom to top), the dummy gate dielectric layer 300 crossing the stacked-layer structure, the dummy gate layer covering the dummy gate dielectric layer 300, and the gate spacer 400 on the sidewall of the dummy gate layer may be first formed; a portion of the dummy gate dielectric layer 300 may be then removed to expose the sidewall of the sacrificial layer; a portion of the sacrificial layer may be then removed through exposed sidewall of the sacrificial layer to form a groove; after forming the inner spacer 260 in the groove, the dummy gate layer, the dummy gate dielectric layer 300 covered by the dummy gate layer, and the sacrificial layer may be removed; and the gate structure 600 crossing the channel-layer structure 270 and surrounding the channel layer 220 may be formed at corresponding position. Therefore, the dummy gate dielectric layer 300 may be retained between the gate spacer 400 and the channel-layer structure 270; and one end of the dummy gate dielectric layer 300 may be in contact with the gate structure 600, and another end of the dummy gate dielectric layer 300 may be recessed relative to the outer sidewall of the gate spacer 400.

It should be noted that the outer sidewall of the gate spacer 400 refers to the sidewall of the gate spacer 400 facing away from the gate structure 600.

During the semiconductor manufacturing process, when the portion of the sacrificial layer 210 is subsequently removed to form the groove, the part which is closer to the edge of the sacrificial layer 210 may be more difficult to be removed. Particularly at the contact position between the stacked-layer structure 200 and the dummy gate dielectric layer 300, oxygen in the dummy gate dielectric layer 300 may diffuse into the sacrificial layer 210, which may be more difficult to remove the material at the contact position between the sacrificial layer 210 and the dummy gate dielectric layer 300. In one embodiment, a portion of the dummy gate dielectric layer 300 may be removed from the sidewall of the stacked-layer structure 200 along the extension direction of the channel layer 220, thereby exposing the sidewall of the sacrificial layer 210. That is, the portion of the sacrificial layer 210 originally in contact with the dummy gate dielectric layer 300 may be exposed, such that the part near the edge of the sacrificial layer 210 along the direction perpendicular to the extension direction of the channel layer 220 may be easily to be removed. In the operation of removing the portion of the sacrificial layer along the extension direction of the channel layer 220 through the exposed portion (sidewall) of the sacrificial layer, the process window of removing the portion of the sacrificial layer may be increased, which may be beneficial for ensuring sufficient space at two sides of the groove along the direction perpendicular to the extension direction of the channel layer 220. In such way, the space for forming the inner spacer 260 may be sufficient, which may be beneficial for ensuring that the inner spacer 260 has sufficient thickness at two sides along the direction perpendicular to the extension direction of the channel layer 220, thereby being beneficial for ensuring the isolation effect of the inner spacer 260. During the operation of removing the sacrificial layer, it is beneficial for ensuring the protection of the inner spacer 260 on the external structure and reducing the probability of damage to the external structure of the inner spacer 260 due to excessive thinness of the inner spacer 260 at two sides along the direction perpendicular to the extension direction of the channel layer 220 during the removal of the sacrificial layer. Accordingly, during the process of forming the gate structure 600, the isolation effect between the gate structure 600 and the external structure of the inner spacer 260 may be ensured, thereby being beneficial for improving the operating performance of the semiconductor structure.

In one embodiment, between the gate spacer 400 and the channel-layer structure 270, the bottom of the gate spacer 400 and the end of the dummy gate dielectric layer 300 which is recessed relative to the outer sidewall of the gate spacer 400 may form a recess 240; and the recess 240 may surround the top and the sidewall of the channel-layer structure 270.

That is, the end of the dummy gate dielectric layer 300 facing away from the gate structure 600 may be recessed relative to the outer sidewall of the gate spacer 400; and such end, the top and the sidewall of the gate spacer 400 at the position that the gate spacer 400 crosses the channel-layer structure 270, and the top and the sidewall of the channel-layer structure 270 may together form the recess 240.

In one embodiment, the distance d between the outer sidewall of the gate spacer 400 and the end of the dummy gate dielectric layer 300 that is recessed relative to the outer sidewall of the gate spacer 400 may be about 3 Å to 20 Å. Therefore, sufficient width of the dummy gate dielectric layer 300 may be removed to expose the sidewall of the sacrificial layer, which may be beneficial for the process of removing the portion of the sacrificial layer to form the groove and may not cause excessive process difficulty in removing the portion of the dummy gate dielectric layer 300.

In one embodiment, the dummy gate dielectric layer 300 may be made of silicon oxide.

The inner spacer 260 may be configured to isolate the gate structure 600 from the source-drain doped layer, thereby reducing parasitic capacitance between the gate structure 600 and the source-drain doped layer.

In one embodiment, during the semiconductor manufacturing process, a portion of the dummy gate dielectric layer 300 may be removed to form the recess 240 exposing the sidewall of the sacrificial layer. Subsequently, a portion of the sacrificial layer may be removed through the exposed sidewall of the sacrificial layer to form the groove. The inner spacer 260 may be then formed in the groove, such that the recess 240 may be connected to the groove. Therefore, in one embodiment, the inner spacer 260 may also fill the recess 240.

In one embodiment, the inner spacer 260 may be made of a material including a dielectric material which may desirably isolate the gate structure 600 and the source-drain doped layer 500.

For example, in one embodiment, the inner spacer 260 may be made of a material including silicon nitride (SiN), silicon oxynitride (SiON), silicon oxycarbonitride (SiOCN), silicon oxycarbide (SiOC), hydrogenated silicon oxycarbide (SiOCH) and/or a combination thereof. SiN, SiON, SiOCN, SiOC, or SiOCH may have a relatively low k value, thereby being beneficial for the isolation between the gate structure 600 and the source-drain doped layer and reducing parasitic capacitance between the gate structure 600 and the source-drain doped layer.

In one embodiment, the semiconductor structure may further include the source-drain doped layer 500 on the base substrate 100 at two sides of the gate structure 600. The source-drain doped layer 500 may be in contact with the ends of the channel-layer structure 270.

The source-drain doped layer 500 may be configured as the source region or the drain region of the transistor. For example, the doping type of the source-drain doped layer 500 may be same as the channel conductivity type of corresponding transistor.

In one embodiment, the isolation effect of the inner spacer 260 at two sides along the direction perpendicular to the extension direction of the channel layer 220 may be ensured. Correspondingly, during the operation of removing the sacrificial layer, the probability of damaging the source-drain doped layer 500 by penetrating (etching through) the inner spacer 260 may be reduced. Furthermore, during the formation of the gate structure 600, the isolation effect between the gate structure 600 and the source-drain doped layer 500 may be effectively maintained, thereby improving the performance of the semiconductor structure.

FIGS. 12-31 illustrate structural schematics corresponding to certain stages of an exemplary fabrication method of a semiconductor structure according to various disclosed embodiments of the present disclosure.

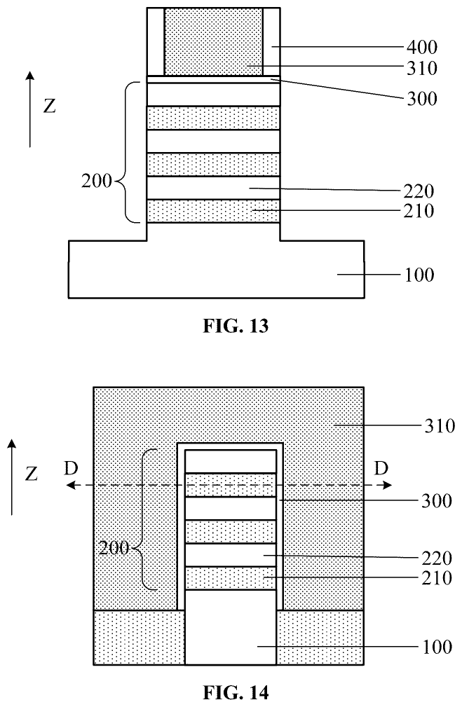

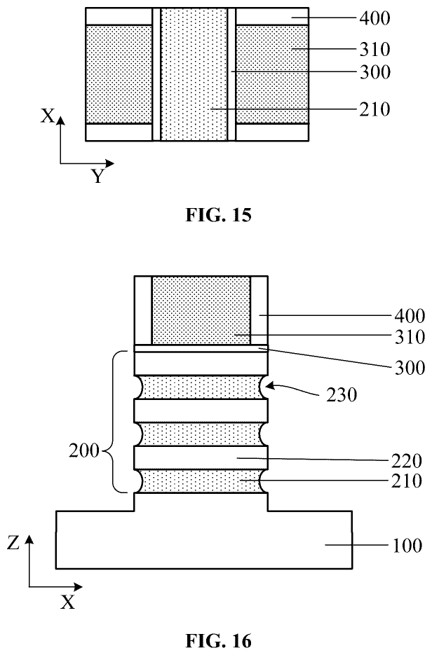

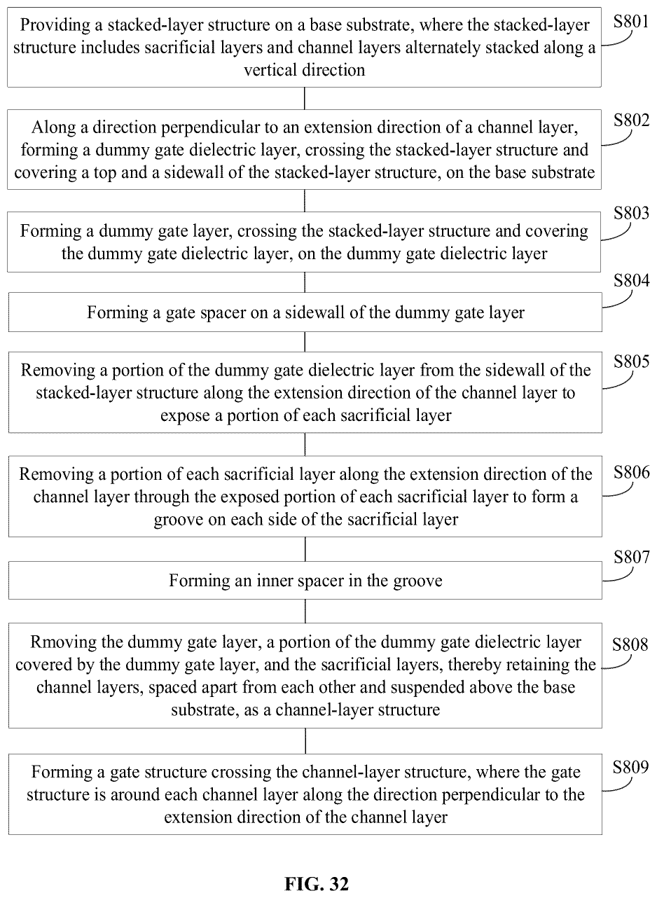

FIG. 12 illustrates a top view of a semiconductor structure, FIG. 13 illustrates a cross-sectional view along the AA direction in FIG. 12, FIG. 14 illustrates a cross-sectional view along the BB direction in FIG. 12, and FIG. 15 illustrates a cross-sectional view along the DD direction in FIG. 12. Referring to FIGS. 12-15, the base substrate 100 may be provided; a stacked-layer structure 200 may be formed on the base substrate 100, where the stacked-layer structure 200 may include sacrificial layers 210 and channel layers 220 alternately stacked from bottom to top along the vertical direction (the Z direction as shown in FIG. 13); the dummy gate dielectric layer 300, crossing the stacked-layer structure 200 and covering the top and the sidewall of the stacked-layer structure 200, may be also formed over the base substrate 100; a dummy gate layer 310, crossing the stacked-layer structure 200 and covering the dummy gate dielectric layer 300, may be formed on the dummy gate dielectric layer 300; and the gate spacer 400 may be formed on the sidewall of the dummy gate layer 310 (e.g., in S801-S804 of FIG. 32).

The base substrate 100 may provide the process operation basis (foundation) for the fabrication process of the semiconductor structure. The semiconductor structures may include gate-all-around (GAA) transistors and fork-sheet transistors.

In some embodiments, the base substrate 100 may be made of silicon. In other embodiments, the base substrate may also be made of other materials including germanium, silicon germanium, silicon carbide, gallium arsenide, indium gallium and/or the like. The base substrate may also be made of other types of substrates including a silicon-on-insulator substrate, a germanium-on-insulator substrate and/or the like. The material of the base substrate may be a material suitable for process needs or easy to integrate.

The channel layer 220 in the stacked-layer structure 200 may be configured as the channel of the semiconductor structure. The sacrificial layer 210 may be configured to provide the process basis for subsequent suspended configuration of the channel layer 220 and may also be configured to occupy space for the gate structure subsequently formed. In subsequent manufacturing process, the sacrificial layers 210 may be removed, such that the channel layers 220 may be suspended; and the gate structure may be formed between the channel layer 220 and the base substrate 100, and between adjacent channel layers 220.

The surface of the channel layer 220 covered by the gate structure may be configured as the channel. In one embodiment, the top, the bottom, and the sidewall of the channel layer 220 may all function as the channel, which may increase the area of the channel layer 220 available for the channel, thereby increasing the operating current of the semiconductor structure.

In one embodiment, during the operation of providing the base substrate 100, the channel layer 220 may be made of a material including silicon, germanium, silicon germanium, a Group III-V semiconductor material, or a combination thereof. In one embodiment, the material of the channel layer 220 may be silicon. In other embodiments, the material of the channel layer may be determined by the type and performance of the transistor.

In one embodiment, during the operation of providing the base substrate 100, the material of the sacrificial layer 210 may include silicon germanium.

SiGe may have lower etching resistance than silicon and may achieve relatively high etching selectivity with silicon. Therefore, during subsequent removal of the sacrificial layer 210, the sacrificial layer 210 may be easily removed; and the damage to the channel layer 220 may be reduced when the sacrificial layer 210 is removed.

In other embodiments, depending on the material of the channel layer, the sacrificial layer may be made of a material that has a suitable etching selectivity with the channel layer, such that the damage to the channel layer may be reduced when the sacrificial layer is removed.

The dummy gate dielectric layer 300 may be configured to protect the stacked-layer structure 200 under the dummy gate dielectric layer 300 from damage during the semiconductor manufacturing process.

In one embodiment, the dummy gate dielectric layer 300 may be made of silicon oxide.

The dummy gate layer 310 may be configured to occupy space for subsequent formation of the gate structure.

The dummy gate layer 310 may be a single layer or a stacked layer structure. The dummy gate layer 310 may be made of a material including amorphous silicon and polycrystalline silicon. In other embodiments, the dummy gate layer may also be made of a material including silicon oxide, silicon nitride, silicon oxynitride, silicon carbide, silicon nitride-carbon, silicon oxynitride, amorphous carbon, and/or a combination thereof.

In one embodiment, the dummy gate layer 310 may be a single-layer structure, and the material of the dummy gate layer 310 may be amorphous silicon. Amorphous silicon has no crystal orientation, such that etching rate and etching uniformity for amorphous silicon may be desirable, thereby improving subsequent removal of the dummy gate layer 310.

The gate spacer 400 may be configured to protect the sidewall of the gate structure.

In one embodiment, the gate spacer 400 may be a single-layer structure or a stacked-layer structure. The gate spacer 400 may be made of a material including silicon oxide, silicon nitride, silicon carbide, silicon carbonitride, silicon oxycarbonitride, silicon oxynitride, boron nitride, boron carbonitride, and/or a combination thereof. In one embodiment, the gate spacer 400 may be a single-layer structure and made of silicon nitride.

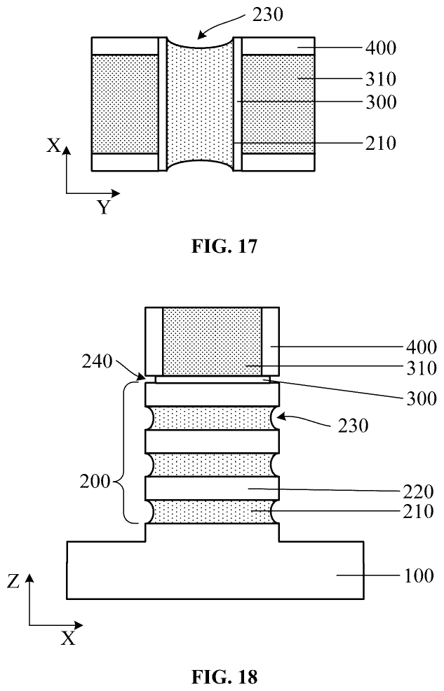

FIG. 16 illustrates a cross-sectional view corresponding to FIG. 14, and FIG. 17 illustrates a cross-sectional view corresponding to FIG. 15. Referring to FIG. 16-17, before subsequently removing a portion of the dummy gate dielectric layer 300 from the sidewall of the stacked-layer structure 200 along the extension direction of the channel layer 220 (the X direction as shown in FIG. 16) to expose the sidewall of the sacrificial layer 210, the fabrication method may further include removing a portion of the sacrificial layer 210 from the sidewall of the stacked-layer structure 200 along the extension direction of the channel layer 220 to form an initial groove 230 surrounded by adjacent channel layers 220 along the vertical direction.

A portion of the sacrificial layer 210 may be first removed, which may prepare for subsequent removal of a portion of the sacrificial layer 210 to form the groove.

In one embodiment, an isotropic etching process may be configured to remove a portion of the sacrificial layer 210 from the sidewall of the stacked-layer structure 200 along the extension direction of the channel layer 220 to form the initial groove 230 which is surrounded by adjacent channel layers 220 along the vertical direction.

The isotropic etching process may have relatively low process cost and simple step and achieve relatively high etching selectivity, thereby being beneficial for reducing damage to the surface of the channel layer 210 during the removal of the portion of the sacrificial layer 220.

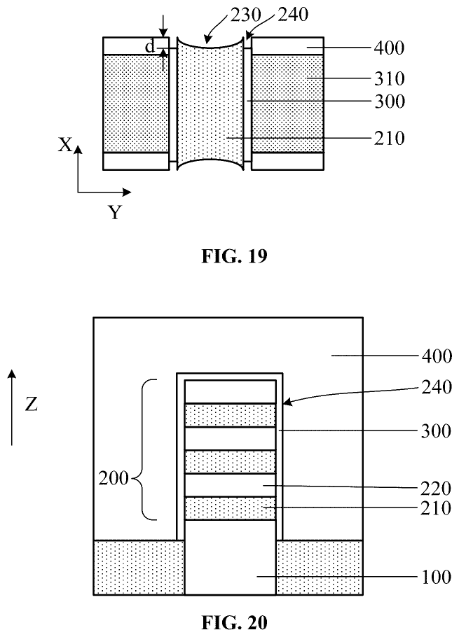

FIG. 18 illustrates a cross-sectional view corresponding to FIG. 16, FIG. 19 illustrates a cross-sectional view corresponding to FIG. 17, and FIG. 20 illustrates a cross-sectional view along the CC direction in FIG. 12. Referring to FIGS. 18-20, from the sidewall of the stacked-layer structure 200, a portion of the dummy gate dielectric layer 300 may be removed along the extension direction of the channel layer 220, thereby exposing the sidewall (portion) of the sacrificial layer 210 (e.g., in S805 of FIG. 32).

A portion of the dummy gate dielectric layer 300 may be removed to expose the sidewall of the sacrificial layer 210, which may be beneficial for increasing the process window for subsequent removal of a portion of the sacrificial layer 210 along the extension direction of the channel layer 220.

For example, in one embodiment, a portion of the dummy gate dielectric layer 300 may be removed from the sidewalls of the stacked-layer structure 200 along the extension direction of the channel layer 220, thereby exposing the sidewalls of the sacrificial layer 210 along two sides of the extension direction perpendicular to the channel layer 220.

During the semiconductor manufacturing process, when the portion of the sacrificial layer 210 is subsequently removed to form the groove, the part which is closer to the edge of the sacrificial layer 210 may be more difficult to be removed. Particularly at the contact position between the stacked-layer structure 200 and the dummy gate dielectric layer 300, oxygen in the dummy gate dielectric layer 300 may diffuse into the sacrificial layer 210, which may be more difficult to remove the material at the contact position between the sacrificial layer 210 and the dummy gate dielectric layer 300. In one embodiment, a portion of the dummy gate dielectric layer 300 may be removed from the sidewall of the stacked-layer structure 200 along the extension direction of the channel layer 220, thereby exposing the sidewall of the sacrificial layer 210. That is, the portion of the sacrificial layer 210 originally in contact with the dummy gate dielectric layer 300 may be exposed, such that the part near the edge of the sacrificial layer 210 along the direction perpendicular to the extension direction of the channel layer 220 may be easily to be removed.

For example, in one embodiment, during the operation of removing the portion of the dummy gate dielectric layer 300 from the sidewall of the stacked-layer structure 200 along the extension direction of the channel layer 220 to expose the sidewall of the sacrificial layer 210, the sidewalls of the sacrificial layer 210 at two sides of the initial groove 230 along the direction perpendicular to the extension direction of the channel layer 220 may be exposed.

In one embodiment, during the operation of removing the portion of the dummy gate dielectric layer 300 from the sidewall of the stacked-layer structure 200 along the extension direction of the channel layer 220 to expose the sidewall of the sacrificial layer 210, a portion of the dummy gate dielectric layer 300 may be removed from the sidewall of the stacked-layer structure 200 along the extension direction of the channel layer 220, and between the gate spacer 400 and the stacked-layer structure 200, the recess 240 surrounding the top and the sidewall of the stacked-layer structure 200 may be formed.

The recess 240 may be subsequently configured as space for forming the inner spacer.

In one embodiment, during the operation of removing the portion of the dummy gate dielectric layer 300 from the sidewall of the stacked-layer structure 200 along the extension direction of the channel layer 220 to expose the sidewall of the sacrificial layer 210, the width d of removed dummy gate dielectric layer 300 may be about 3 Å to 20 Å. In such way, sufficient width of the dummy gate dielectric layer 300 may be removed to expose the sidewall of the sacrificial layer 210, which may be beneficial for the process of removing the portion of the sacrificial layer to form the groove and may not cause excessive process difficulty in removing the portion of the dummy gate dielectric layer 300.

In one embodiment, an isotropic etching process may be configured to remove the portion of the dummy gate dielectric layer 300 from the sidewall of the stacked-layer structure 200 along the extension direction of the channel layer 220 to expose the sidewall of the sacrificial layer 210.

The isotropic etching process may have relatively low process cost and simple step and achieve relatively high etching selectivity, thereby being beneficial for reducing damage to the surface of the channel layer 220 during the removal of the portion of the dummy gate dielectric layer 300.

In one embodiment, during the operation of removing the portion of the dummy gate dielectric layer 300, by the isotropic etching process, from the sidewall of the stacked-layer structure 200 along the extension direction of the channel layer 220 to expose the sidewall of the sacrificial layer 210, the etching process may have an etching selectivity ratio of greater than or equal to 5 between the dummy gate dielectric layer 300 and the channel layer 220, which may be beneficial for easily etching the dummy gate dielectric layer 300 while reducing damage to the surface of the channel layer 220.

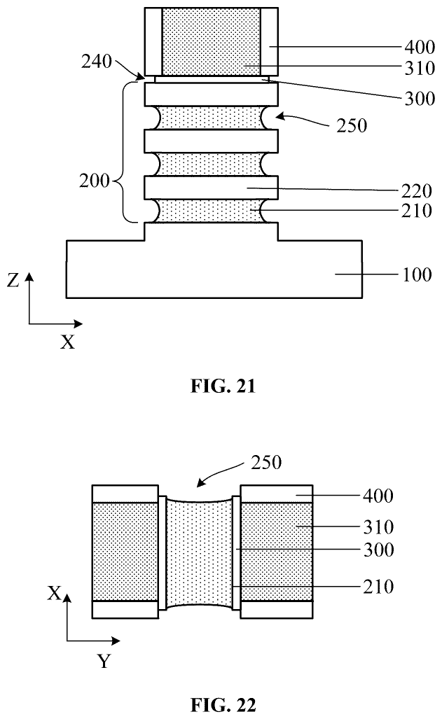

FIG. 21 illustrates a cross-sectional view corresponding to FIG. 18, and FIG. 22 illustrates a cross-sectional view corresponding to FIG. 19. Referring to FIGS. 21-22, a portion of the sacrificial layer 210 may be removed, along the extension direction of the channel layer 220, through the exposed sidewall of the sacrificial layer 210, to form a groove 250 (e.g., in S806 of FIG. 32).

The groove 250 may be configured to provide space for subsequent formation of the inner spacer.

In one embodiment, during the operation of removing the portion of the sacrificial layer 210 along the extension direction of the channel layer 220 through the exposed sidewall of the sacrificial layer 210, the process window for removing the portion of the sacrificial layer 210 may be increased, which may be beneficial for ensuring sufficient space at two sides of the groove 250 along the direction perpendicular to the extension direction of the channel layer 220 and providing sufficient space for subsequent formation of the inner spacer.

For example, in one embodiment, during the operation of removing the portion of the sacrificial layer 210 along the extension direction of the channel layer 220 through the exposed sidewall of the sacrificial layer 210, a portion of the sacrificial layer 210 may be removed through the initial groove 230 and the exposed sidewall of the sacrificial layer 210 of the dummy gate dielectric layer 300 to form the groove 250.

In one embodiment, an isotropic etching process may be configured to remove the portion of the sacrificial layer 210 along the extension direction of the channel layer 220 through the exposed sidewall of the sacrificial layer 210 to form the groove 250.

The isotropic etching process may have relatively low process cost and simple step and achieve relatively high etching selectivity, thereby being beneficial for reducing damage to the surface of the channel layer 220 during the removal of the portion of the sacrificial layer 210.

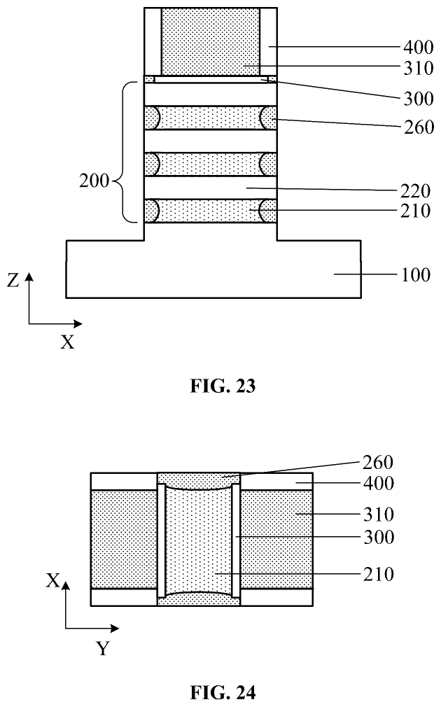

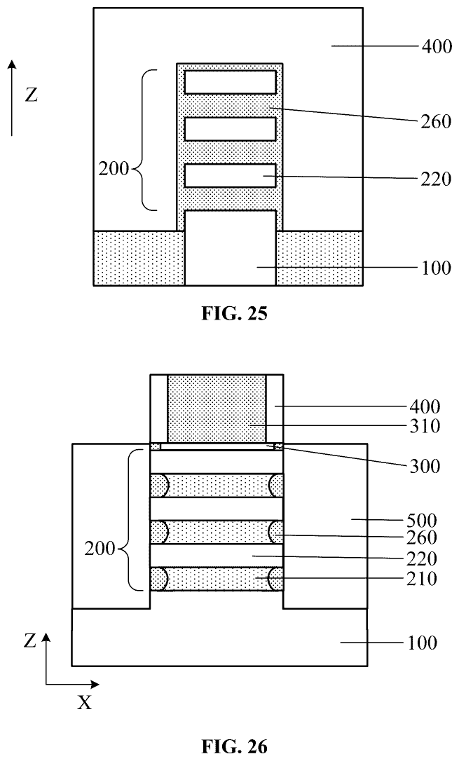

FIG. 23 illustrates a cross-sectional view corresponding to FIG. 21, FIG. 24 illustrates a cross-sectional view corresponding to FIG. 22, and FIG. 25 illustrates a cross-sectional view corresponding to FIG. 20. Referring to FIGS. 23-25, the inner spacer 260 may be formed in the groove 250 (e.g., in S807 of FIG. 32).

The inner spacer 260 may be configured to isolate the gate structure subsequently formed from the source-drain doped layer, thereby reducing parasitic capacitance between the gate structure and the source-drain doped layer.

Accordingly, in one embodiment, during the operation of forming the inner spacers 260 in the groove 250, the inner spacer 260 may also be filled in the recess 240.

In one embodiment, sufficient space may be at two sides of the groove 250 along the direction perpendicular to the extension direction of the channel layer 220, such that space for forming the inner spacer 260 may be sufficient, which may be beneficial for ensuring that the inner spacer 260 has sufficient thickness at two sides along the direction perpendicular to the extension direction of the channel layer 220, thereby ensuring the isolation effect of the inner spacer 260.

In one embodiment, during the operation of forming the inner spacer 260 in the groove 250, the inner spacer 260 may be made of a material including a dielectric material which may desirably isolate the gate structure from the source-drain doped layer.

For example, in one embodiment, the inner spacer 260 may be made of a material including SiN, SiON, SiOCN, SiOC, SiOCH and/or a combination thereof. SiN, SiON, SiOCN, SiOC, or SiOCH may have a relatively low k value, thereby being beneficial for the isolation between the gate structure and the source-drain doped layer and reducing parasitic capacitance between the gate structure and the source-drain doped layer.

FIG. 26 illustrates a cross-sectional view corresponding to FIG. 23. Referring to FIG. 26, after forming the inner spacer 260 in the groove 250 and before subsequently removing the dummy gate layer 310, the dummy gate dielectric layer 300 covered by the dummy gate layer 310, and the sacrificial layer 210, the fabrication method may further include forming source-drain doped layer 500 on the base substrate 100 at two sides of the dummy gate layer 310 along the extension direction of the channel layer 220; and the source-drain doped layer 500 may be in contact with the ends of the stacked-layer structure 200.

The source-drain doped layer 500 may be configured as the source region or the drain region of the transistor. For example, the doping type of the source-drain doped layer 500 may be same as the channel conductivity type of corresponding transistor.

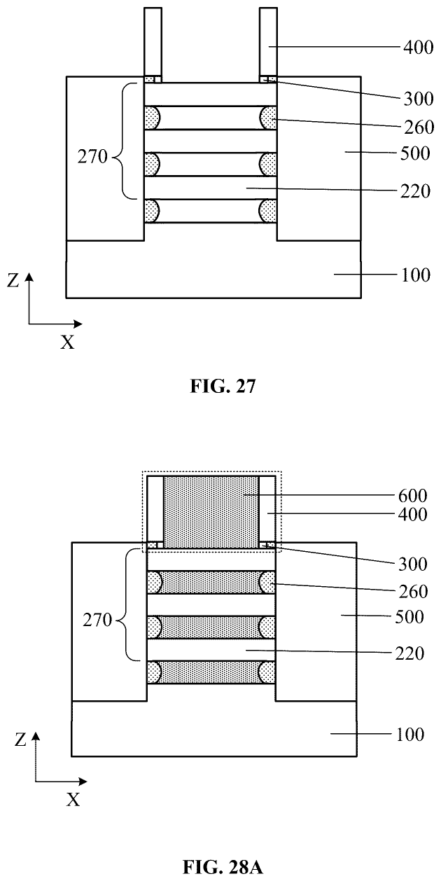

Referring to FIG. 27, the dummy gate layer 310, the dummy gate dielectric layer 300 covered by the dummy gate layer 310, and the sacrificial layer 210 may be removed; and the channel layers 220, spaced apart from each other and suspended above the base substrate 100, may be retained as the channel-layer structure 270 (e.g., in S808 of FIG. 32).

The dummy gate layer 310, the dummy gate dielectric layer 300 covered by the dummy gate layer 310, and the sacrificial layer 210 may be removed, which may provide space for subsequent formation of the gate structure.

In one embodiment, the inner spacer 260 may have sufficient thickness at two sides along the direction perpendicular to the extension direction of the channel layer 220, which may be beneficial for ensuring the protection of the inner spacer 260 on the external structure and reducing the probability of damage to the external structure of the inner spacer 260 due to excessive thinness of the inner spacer 260 at two sides along the direction perpendicular to the extension direction of the channel layer 220 during the removal of the sacrificial layer 210. Accordingly, during the process of forming the gate structure subsequently, the isolation effect between the gate structure and the external structure of the inner spacer 260 may be ensured, thereby being beneficial for improving the operating performance of the semiconductor structure.

For example, in one embodiment, during the operation of removing the dummy gate layer 310, the dummy gate dielectric layer 300 covered by the dummy gate layer 310, and the sacrificial layer 210, the dummy gate layer 310 may be removed to expose the dummy gate dielectric layer 300 between adjacent gate spacers 400.

Removing the dummy gate layer 310 to expose the dummy gate dielectric layer 300 between adjacent gate spacers 400 may be configured to prepare for removal of the dummy gate dielectric layer 300.

In one embodiment, the dummy gate dielectric layer 300 exposed by the gate spacers 400 may be removed to expose the stacked-layer structure 200.

Removing the dummy gate dielectric layer 300 exposed by the gate spacers 400 to expose the stacked-layer structure 200 may be configured to prepare for subsequent removal of the sacrificial layer 210.

In one embodiment, the sacrificial layers 210 in the stacked-layer structure 200 may be removed, and one or more channel layers 220 spaced apart from each other and suspended above the base substrate 100 may be configured as the channel-layer structure 270.

In one embodiment, for the operation of removing the sacrificial layer 210, it may be beneficial for ensuring the protective effect of the inner spacer 260 on the source-drain doped layer 500, and reducing the probability of damage to the source-drain doped layer 500 during removal of the sacrificial layer 210.

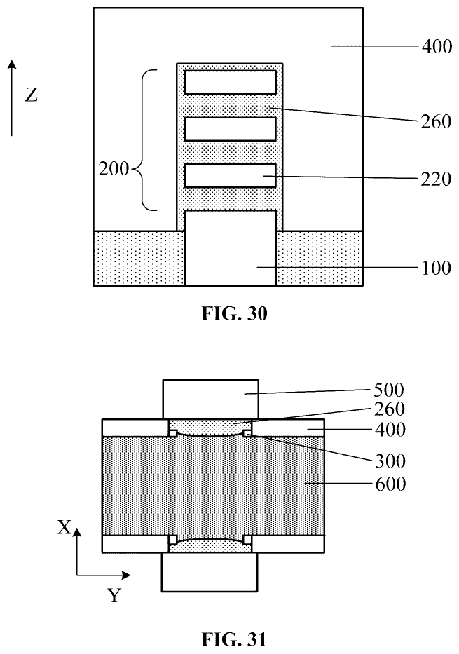

FIG. 28A illustrates a cross-sectional view corresponding to FIG. 27, FIG. 28B illustrates an enlarged schematic of a dashed-rectangle region in FIG. 28A, FIG. 29 illustrates a cross-sectional view corresponding to FIG. 14, FIG. 30 illustrates a cross-sectional view corresponding to FIG. 25, and FIG. 31 illustrates a cross-sectional view corresponding to FIG. 24. Referring to FIGS. 28-31, the gate structure 600, crossing the channel-layer structure 270, may be formed, and surround the channel layer 220 along the direction perpendicular to the extension direction of the channel layer 220 (e.g., in S809 of FIG. 32).

The gate structure 600 may be configured to control the turn-on and turn-off state of the transistor channel.

The gate structure 600 may be around and cover the channel layer 220. Therefore, the top, the bottom, and the sidewall of the channel layer 220 may all function as the channel, which may increase the area of the channel layer 220 available for the channel, thereby increasing the operating current of the semiconductor structure.

In one embodiment, the gate structure 600 may include a gate dielectric layer 603 (referring to FIG. 28B) surrounding the channel layer 220 along the extension direction of the gate structure 600, and a gate structure 601 (referring to FIG. 28B) on the gate dielectric layer.

The gate dielectric layer may be configured to isolate the gate structure from both the channel layer 220 and the base substrate 100.

The gate dielectric layer may be made of a material including HfO₂, ZrO₂, HfSiO, HfSiON, HfTaO, HfTiO, HfZrO, Al₂O₃, SiO₂, La₂O₃, and/or a combination thereof. In one embodiment, the gate dielectric layer may include a high-k gate dielectric layer; and the material of the high-k gate dielectric layer may include a high-k dielectric material. The high-k dielectric material refers to a dielectric material having a relative dielectric constant greater than the relative dielectric constant of silicon oxide. For example, the high-k gate dielectric layer may be made of a material including HfO₂, ZrO₂, HfSiO, HfSiON, HfTaO, HfTiO, HfZrO, Al₂O₃, and/or a combination thereof.

It should be noted that the gate dielectric layer may also include a gate oxide layer; and the gate oxide layer may be between the high-k gate dielectric layer and the channel layer 220. For example, the gate oxide layer may be made of silicon oxide.

In one embodiment, the gate structure 600 may be a metal gate structure. Therefore, the gate structure may be made of a material including TiN, TaN, Ta, Ti, TiAl, W, Al, TiSiN, TiAlC, and/or a combination thereof.

For example, the gate structure may include a work function layer (not shown), and an electrode layer (not shown) on the work function layer. The work function layer may be configured to adjust the threshold voltage of the transistor, and the electrode layer may be configured to lead out the electrical properties of the metal gate structure.

In other embodiments, the gate structure may include only the work function layer.

In other embodiments, according to process requirements, the gate structure may also be a polysilicon gate structure.

Although the present disclosure has been disclosed above, the present disclosure may be not limited thereto. Any changes and modifications may be made by those skilled in the art without departing from the spirit and scope of the disclosure, and the scope of the disclosure should be determined by the scope defined by the appended claims.

What is claimed is:

1. A semiconductor structure, comprising:
a base substrate;
a channel-layer structure, suspended above the base substrate, wherein the channel-layer structure includes one or more channel layers spaced apart from each other along a vertical direction;
a gate structure, over the substrate and crossing the channel-layer structure, wherein the gate structure is around the one or more channel layers along a direction perpendicular to an extension direction of a channel layer of the one or more channel layers;
a gate spacer, crossing the channel-layer structure and covering a sidewall of the gate structure;
a dummy gate dielectric layer, between the gate spacer and the channel-layer structure and covering a portion of a sidewall and a portion of a top of the channel-layer structure at a position that the gate spacer crosses the channel-layer structure, wherein along the extension direction of the channel layer, an end of the dummy gate dielectric layer is in a contact with the gate structure, and another end of the dummy gate dielectric layer is recessed relative to an outer sidewall of the gate spacer; and
an inner spacer, on a sidewall of the gate structure between adjacent channel layers.

2. The semiconductor structure according to claim 1, wherein:
between the gate spacer and the channel-layer structure, the another end of the dummy gate dielectric layer, which is recessed relative to the outer sidewall of the gate spacer, and a bottom of the gate spacer form a recess, the recess surrounding the top and the sidewall of the channel-layer structure; and
the inner spacer is further filled in the recess.

3. The semiconductor structure according to claim 1, wherein:
a distance between the outer sidewall of the gate spacer and the another end of the dummy gate dielectric layer recessed relative to the outer sidewall of the gate spacer is about 3 Å to 20 Å.

4. The semiconductor structure according to claim 1, further including:
a source-drain doped layer, on the base substrate at two sides of the gate structure, wherein the source-drain doped layer is in a contact with an end of the channel-layer structure.

5. The semiconductor structure according to claim 1, wherein:
the channel layer is made of a material including silicon, germanium, silicon germanium, a Group III-V semiconductor material, or a combination thereof.

6. The semiconductor structure according to claim 1, wherein:
the gate spacer is made of a material including silicon oxide, silicon nitride, silicon carbide, silicon carbonitride, silicon oxycarbonitride, silicon oxynitride, boron nitride, boron carbonitride, or a combination thereof.

7. The semiconductor structure according to claim 1, wherein:
the inner spacer is made of a material including silicon nitride, silicon oxynitride, silicon oxycarbonitride, silicon oxycarbide, hydrogenated silicon oxycarbide, or a combination thereof.

8. A fabrication method of a semiconductor structure, comprising:
providing a stacked-layer structure on a base substrate, wherein the stacked-layer structure includes sacrificial layers and channel layers alternately stacked along a vertical direction;
along a direction perpendicular to an extension direction of a channel layer, forming a dummy gate dielectric layer, crossing the stacked-layer structure and covering a top and a sidewall of the stacked-layer structure, on the base substrate;
forming a dummy gate layer, crossing the stacked-layer structure and covering the dummy gate dielectric layer, on the dummy gate dielectric layer;
forming a gate spacer on a sidewall of the dummy gate layer;
removing a portion of the dummy gate dielectric layer from the sidewall of the stacked-layer structure along the extension direction of the channel layer to expose a portion of each sacrificial layer;
removing a portion of each sacrificial layer along the extension direction of the channel layer through the exposed portion of each sacrificial layer to form a groove on each side of the sacrificial layer;
forming an inner spacer in the groove;
removing the dummy gate layer, a portion of the dummy gate dielectric layer covered by the dummy gate layer, and the sacrificial layers, thereby retaining the channel layers, spaced apart from each other and suspended above the base substrate, as a channel-layer structure; and
forming a gate structure crossing the channel-layer structure, wherein the gate structure is around each channel layer along the direction perpendicular to the extension direction of the channel layer.

9. The fabrication method according to claim 8, wherein:
for removing the portion of the dummy gate dielectric layer from the sidewall of the stacked-layer structure along the extension direction of the channel layer to expose the portion of each sacrificial layer, the portion of the dummy gate dielectric layer is removed from the sidewall of the stacked-layer structure along the extension direction of the channel layer to form a recess, wherein the recess surrounds a top and a sidewall of the stacked-layer structure between the gate spacer and the stacked-layer structure; and
for forming the inner spacer in the groove, the inner spacer is further filled in the recess.

10. The fabrication method according to claim 8, wherein:
for removing the portion of the dummy gate dielectric layer from the sidewall of the stacked-layer structure along the extension direction of the channel layer to expose the portion of each sacrificial layer, a width of removed dummy gate dielectric layer is about 3 Å to 20 Å.

11. The fabrication method according to claim 8, wherein:
an isotropic etching process is configured to remove the portion of the dummy gate dielectric layer from the sidewall of the stacked-layer structure along the extension direction of the channel layer to expose the portion of each sacrificial layer.

12. The fabrication method according to claim 11, wherein:
for removing the portion of the dummy gate dielectric layer from the sidewall of the stacked-layer structure along the extension direction of the channel layer by the isotropic etching process, an etching selectivity ratio between the dummy gate dielectric layer and the channel layer is greater than or equal to 5.

13. The fabrication method according to claim 8, wherein:
an isotropic etching process is configured to remove the portion of each sacrificial layer along the extension direction of the channel layer through the exposed portion of each sacrificial layer to form the groove.

14. The fabrication method according to claim 8, wherein:
before removing the portion of the dummy gate dielectric layer from the sidewall of the stacked-layer structure along the extension direction of the channel layer to expose the portion of each sacrificial layer, the method further includes removing a portion of each sacrificial layer from the sidewall of the stacked-layer structure along the extension direction of the channel layer, and forming an initial groove surrounded by adjacent channel layers along a vertical direction;
removing the portion of the dummy gate dielectric layer from the sidewall of the stacked-layer structure along the extension direction of the channel layer to expose the portion of each sacrificial layer includes exposing sidewalls of each sacrificial layer on two sides of the initial groove along a direction perpendicular to the extension direction of the channel layer; and
for removing the portion of each sacrificial layer along the extension direction of the channel layer through the exposed portion of each sacrificial layer to form the groove includes removing the portion of each sacrificial layer through the initial groove and the exposed portion of each sacrificial layer to form the groove.

15. The fabrication method according to claim 14, wherein:
an isotropic etching process is configured to remove the portion of each sacrificial layer from the sidewall of the stacked-layer structure along the extension direction of the channel layer, and form the initial groove surrounded by adjacent channel layers along the vertical direction.

16. The fabrication method according to claim 8, after forming the inner spacer in the groove and before removing the dummy gate layer, the portion of the dummy gate dielectric layer covered by the dummy gate layer and the sacrificial layers, further including:
forming a source-drain doped layer, on the base substrate at two sides of the gate structure, wherein the source-drain doped layer is in a contact with an end of the channel-layer structure.

17. The fabrication method according to claim 8, wherein removing the dummy gate layer, the portion of the dummy gate dielectric layer covered by the dummy gate layer, and the sacrificial layers includes:
removing the dummy gate layer to expose the dummy gate dielectric layer between adjacent gate spacers;
removing the dummy gate dielectric layer between adjacent gate spacers to expose the stacked-layer structure; and
removing the sacrificial layers in the stacked-layer structure, thereby retaining the channel layers, spaced apart from each other and suspended above the base substrate, as the channel-layer structure.

18. The fabrication method according to claim 8, wherein:
for providing the base substrate, the channel layer is made of a material including silicon, germanium, silicon germanium, a Group III-V semiconductor material, or a combination thereof.

19. The fabrication method according to claim 8, wherein:
the gate spacer is made of a material including silicon oxide, silicon nitride, silicon carbide, silicon carbonitride, silicon oxycarbonitride, silicon oxynitride, boron nitride, boron carbonitride, or a combination thereof.

20. The fabrication method according to claim 8, wherein:
the inner spacer is made of a material including silicon nitride, silicon oxynitride, silicon oxycarbonitride, silicon oxycarbide, hydrogenated silicon oxycarbide, or a combination thereof.
